(19) United States
(12) Patent Application Publication
(10) Pub. No.: US 2019/0372511 A1
(43) Pub. Date: Dec. 5, 2019

(54) Photovoltaic Container

(71) Applicant: Gree Electric Appliances, Inc. of Zhuhai, Zhuhai City, Guangdong (CN)

(72) Inventors: Jian WANG, Guangdong (CN); Rongxin LIANG, Guangdong (CN); Jinyuan JIANG, Guangdong (CN); Wenqiang TANG, Guangdong (CN); Congcong FANG, Guangdong (CN)

(21) Appl. No.: 16/327,684

(22) PCT Filed: Apr. 17, 2017
(86) PCT No.: PCT/CN2017/080695

§ 371 Date: Feb. 22, 2019

(30) Foreign Application Priority Data
Dec. 26, 2016 (CN) 201611218651.3

(51) Int. Cl. H02S 20/30; H01L 31/042

(52) U.S. Cl. CPC H02S 20/30; H01L 31/042

(57) ABSTRACT

Disclosed is a photovoltaic container (100), relating to the field of containers. The technical solution mainly adopted is: a photovoltaic container includes a photovoltaic assembly (1), a support frame (2) and a container body (3); wherein the container body (3) includes a container body framework; the photovoltaic assembly (1) is mounted on the container body framework through the support frame (2), and is located outside the container body (3) to make the photovoltaic assembly (1) supported by the container body framework. Because the photovoltaic assembly (1) is mounted on the container body framework of the container (100) through the support frame (2), the container body framework has a higher strength and thus can provide strong support to the photovoltaic assembly (1).

### CROSS REFERENCE TO RELATED APPLICATIONS

This application is a continuation application of PCT Patent Application No. PCT/CN2017/080695, entitled “Photovoltaic Container”, filed on Apr. 17, 2017, which claims priority to Chinese Patent Application No. 201611218651.3, entitled “Photovoltaic Container”, filed on Dec. 26, 2016, the entire contents of which are incorporated herein by reference.

### TECHNICAL FIELD

The present disclosure relates to a container, and more particularly, to a photovoltaic container.

### BACKGROUND

The photovoltaic container generates electricity by means of photovoltaic panels laid on the top surface of the container, and is able to form an independent power supply and utilization system. In recent years, the photovoltaic container is widely used in places where it is difficult to popularize the power facilities such as heath, island and so on, and is especially respected by the military and the fieldworkers working in the severe environment.

However, due to a relatively thin iron sheet of the top layer of the container, if the photovoltaic assembly is directly laid on the top surface of the container, the pressure of the weight of the photovoltaic assembly may easily cause depression and deformation of the iron sheet in the top layer of the container, which goes against the service life of the container. In addition, uneven top surface of the container is difficult to satisfy the technical requirements of laying the photovoltaic assembly; and when directly laying the photovoltaic assembly on the top surface of the container, too many installation procedures and aloft work may increase construction difficulty for the installers.

### SUMMARY

In view of this, the present disclosure provides a photovoltaic container, and the main objective is to solve the technical problem that when the existing photovoltaic assembly is directly laid on the top surface of the container, the pressure of the weight of the photovoltaic assembly may easily cause depression and deformation of the iron sheet in the top layer of the container.

The above-mentioned objective is accomplished with the following technical solutions.

In one aspect, the present disclosure provides a photovoltaic container, including a photovoltaic assembly, a support frame and a container body; wherein the container body includes a container body framework;

the photovoltaic assembly is mounted on the container body framework through the support frame and located outside the container body, to make the photovoltaic assembly supported by the container body framework.

The objective of the present disclosure and the technical measure for solving the technical problem thereof can be further implemented as follows.

In the above-mentioned photovoltaic container, optionally, the photovoltaic assembly is located above a top surface of the container body;

the photovoltaic assembly is mounted on the support fame which is mounted on a first part of the container body framework, the first part is located on a top of the container body.

In the above-mentioned photovoltaic container, optionally, the photovoltaic container further includes a horizontal adjustment footstand;

the support frame is mounted on the container body framework through the horizontal adjustment footstand, to adjust horizontality of the photovoltaic assembly on the support frame through the horizontal adjustment footstand.

In the above-mentioned photovoltaic container, optionally, the photovoltaic container has at least two layers of photovoltaic assemblies in a vertical direction;

wherein, each layer of photovoltaic assemblies is moveable relative to one another, to move to a first relative position at which the layers of photovoltaic assemblies overlap each other in the vertical direction and a second relative position at which the layers of photovoltaic assemblies are spread out relatively.

In the above-mentioned photovoltaic container, optionally, the layers of photovoltaic assemblies have a first layer of photovoltaic assemblies and a second layer of photovoltaic assemblies which are adjacently disposed;

the first layer of photovoltaic assemblies is fixed on the support frame;

the second layer of photovoltaic assemblies is movably disposed on the support frame, to move to the first relative position and the second relative position with respect to the first layer of photovoltaic assemblies.

In the above-mentioned photovoltaic container, optionally, the second layer of photovoltaic assemblies has a first row of photovoltaic assembly and a second row of photovoltaic assembly in a horizontal direction;

the first row of photovoltaic assembly and the second row of photovoltaic assembly can be relatively close to each other, to make the second layer of photovoltaic assemblies located at the first relative position with respect to the first layer of photovoltaic assemblies; and the first row of photovoltaic assembly and the second row of photovoltaic assembly can be relatively far away from each other, to make the second layer of photovoltaic assemblies located in the second relative position with respect to the first layer of photovoltaic assemblies.

In the above-mentioned photovoltaic container, optionally, a linear slide rail is disposed on the support frame, the support frame is connected to each row of photovoltaic assembly in the second layer of photovoltaic assemblies through the linear slide rail, to guide the each row of photovoltaic assembly in the second layer of photovoltaic assemblies;

wherein, the each row of photovoltaic assembly in the second layer of photovoltaic assemblies is connected to the support frame through a lead screw nut structure, to be driven through the lead screw nut structure so as to make the second layer of photovoltaic assemblies located at the first relative position and the second relative position with respect to the first layer of photovoltaic assemblies.

In the above-mentioned photovoltaic container, optionally, the each row of photovoltaic assembly in the second layer of photovoltaic assemblies includes at least one photovoltaic assembly unit;

the photovoltaic assembly unit includes a keel and the photovoltaic assembly mounted on the keel;

the keel is connected to a screw nut platform of the lead screw nut structure and a slide block of the linear slide rail respectively.

In the above-mentioned photovoltaic container, optionally, there are at least two layers of support frames in the vertical direction;

two adjacent layers of the support frames are spaced in the vertical direction, and each layer of photovoltaic assemblies is disposed on a different layer of the support frame from one another in one-to-one correspondence.

In the above-mentioned photovoltaic container, optionally, each layer of the support frame includes a frame structure constructed by connecting a plurality of connecting rods on the same plane;

wherein, two adjacent layers of frame structures are fixedly connected.

The beneficial effects of the photovoltaic container of the present disclosure are provided as follows.

In the technical solution provided by the present disclosure, the photovoltaic container is mounted on the container body framework of the container through the support frame, wherein the container body framework has higher strength and thus can provide strong support to the photovoltaic assembly. Compared to the existing photovoltaic assembly which is mounted on the top of the container and causes deformation of the housing at the top of the container, the container body framework and housing of the photovoltaic container of the present disclosure do not deform, therefore the photovoltaic assembly of the present disclosure has a longer service life.

The above illustration is only a summary of the technical solution of the present disclosure. In order to clarify and implement the technical solution of the present disclosure according to the description, preferred embodiments of the present invention will be detailed below in conjunction with the accompanying drawings.

### BRIEF DESCRIPTION OF DRAWINGS

FIG. 1 is a front view of a photovoltaic container according to an embodiment of the present invention;

FIG. 2 is a front view of a second layer of photovoltaic assemblies on a support frame when it is located at a first relative position with respect to a first layer of photovoltaic assemblies according to an embodiment of the present invention;

FIG. 3 is a front view of a second layer of photovoltaic assemblies on a support frame when it is located at a second relative position with respect to a first layer of photovoltaic assemblies according to an embodiment of the present invention;

FIG. 4 is a top view of a second layer of photovoltaic assemblies on a support frame when it is located at a second relative position with respect to a first layer of photovoltaic assemblies according to an embodiment of the present invention;

FIG. 5 is a top view of a photovoltaic assembly unit according to an embodiment of the present invention;

FIG. 6 is a structural schematic view of a support frame according to an embodiment of the present invention.

### DETAILED DESCRIPTION OF DISCLOSED EMBODIMENTS

In order to make the objectives, the technical schemes and the benefits of the present disclosure more apparent, the present disclosure will be described in more details through the following embodiments, structures, features and advantages in conjunction with the accompanying drawings. In the following description, various “an embodiment” or “embodiment” does not have to refer to the same embodiment. In addition, specific features, structures or characteristics in one or more embodiments can be combined in any appropriate form.

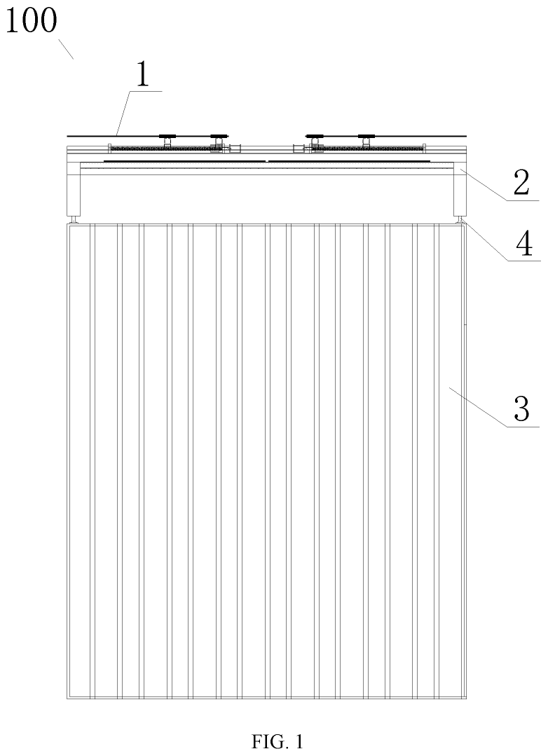

As shown in FIG. 1, according to an embodiment of the present invention, a photovoltaic container 100 includes a photovoltaic assembly 1, a support frame 2 and a container body 3. The container body 3 includes a container body framework. The photovoltaic assembly 1 is mounted on the container body framework through the support frame 2, and is located outside the container body 3, so as to make the photovoltaic assembly 1 supported by the container body framework.

It should be noted that, the above-mentioned container body 3 further includes a container body housing mounted on the container body framework. Wherein, the container body framework has a higher strength and thus can provide support to the container body housing, so as to ensure the structural strength of the whole container body 3 and facilitate the installation of the container body housing.

The above-mentioned container body housing may adopt metal material and so on.

In the above-mentioned technical solution, because the photovoltaic assembly 1 is mounted on the container body framework of the container through the support frame 2, wherein the container body framework has a higher strength and thus can provide strong support to the photovoltaic assembly 1, in contrast to the existing photovoltaic assembly which is mounted on the top of the container and causes deformation of the housing at the container top, the container body framework and housing of the photovoltaic container 100 provided by the present disclosure do not deform, and accordingly, the photovoltaic assembly 1 of the present disclosure has a longer service life.

It should be noted that, the number of the above-mentioned support frame 2 may be two or more, so as to reduce the size and weight of a single support frame 2 and facilitate the workers to mount the support frame 2 onto the container body framework of the container body 3.

Furthermore, as shown in FIG. 1, the above-mentioned photovoltaic assembly 1 may be located above the top surface of the container body 3. The photovoltaic assembly 1 is mounted on the support frame 2, the support frame 2 is mounted on a first part of the container body framework, and the first part is located on the top of the container body 3. In this example, the photovoltaic assembly 1 and the support frame 2 are both located in the open space above the top surface of the container body 3, thus the installation thereof is not limited by the installation space and do not affect a user's walking along the side of the container body 3.

As shown in FIG. 1, the photovoltaic container 100 of the present disclosure may further include a horizontal adjustment footstand 4. The above-mentioned support frame 2 is mounted on the container body framework through the horizontal adjustment footstands 4, so as to adjust the horizontality of the photovoltaic assembly 1 on the support frame 2 by the horizontal adjustment footstands 4. In this example, it is possible to adjust the angle of the photovoltaic assemble 1 by the disposed horizontal adjustment footstands 4 in order to better receive sunlight and improve the working efficiency of the photovoltaic assembly 1.

It should be noted that, the above-mentioned horizontal adjustment footstand 4 is a commercially available component, which can be bought in the market, the details will not be repeated here.

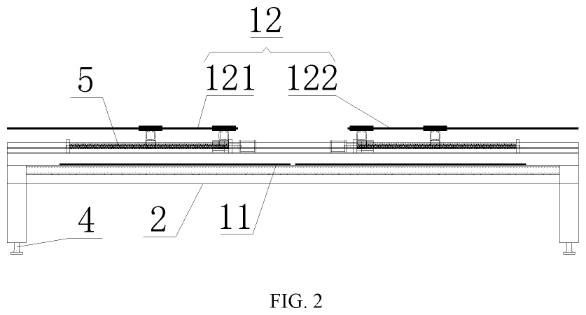

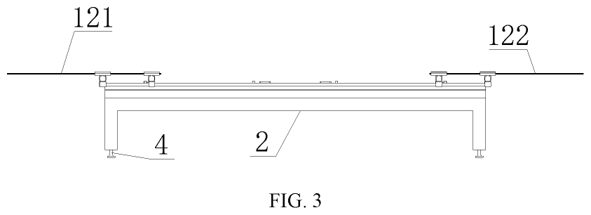

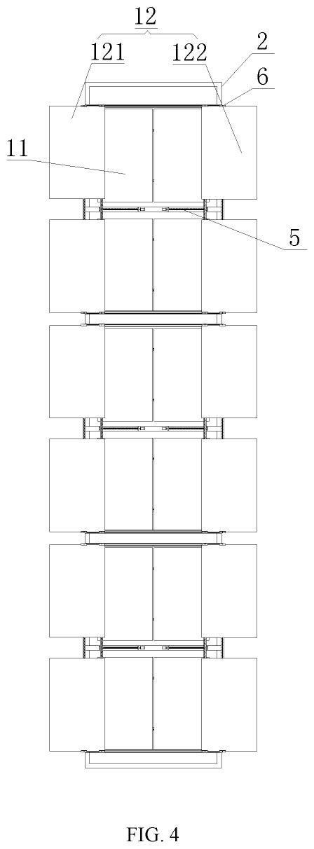

Furthermore, as shown in FIG. 2 to FIG. 4, the photovoltaic container 100 of the present disclosure has at least two layers of photovoltaic assemblies in the vertical direction. Wherein each of the layers of photovoltaic assemblies can be moveable relative to one another, for example, can be moved to a first relative position at which the layers of photovoltaic assemblies overlap each other in the vertical direction (as shown in FIG. 2) and to a second relative position at which the layers of photovoltaic assemblies are spread out relatively (as shown in FIG. 3 and FIG. 4). In this example, by disposing a plurality of layers of photovoltaic assemblies, the number of the photovoltaic assembly 1 can be increased, thereby improving the photovoltaic capacity of the photovoltaic container 100 of the present disclosure.

It should be noted that, when two adjacent layers of photovoltaic assemblies overlap each other in the vertical direction, the two adjacent layers of photovoltaic assemblies may be spaced in the vertical direction or may be contacted with each other. In order to prevent interference between the two adjacent layers of photovoltaic assemblies, preferably, when the two adjacent layers of photovoltaic assemblies overlap each other in the vertical direction, the two adjacent layers of photovoltaic assemblies are spaced in the vertical direction.

The position of the above-mentioned photovoltaic assembly can be switched between the first relative position and the second relative position by rectilinear translation, thereby achieving a technical effect of easy operation.

When implemented, as shown in FIG. 2, the above-mentioned layers of photovoltaic assemblies include a first layer of photovoltaic assemblies 11 and a second layer of photovoltaic assemblies 12 which are adjacently disposed. The first layer of photovoltaic assemblies 11 is fixed on the support frame 2. The second layer of photovoltaic assemblies 12 is movably disposed on the support frame 2, to be moved to the above-mentioned first relative position and second relative position with respect to the first layer of photovoltaic assemblies 11. It is possible that both of the first layer of photovoltaic assemblies 11 and the second layer of photovoltaic assemblies 12 are relatively moveable, but in this example, by fixing the first layer of photovoltaic assemblies 11 and only making the second layer of photovoltaic assemblies movable, the structure of movement mechanism can be simplified and the cost can be saved.

Furthermore, as shown in FIG. 2 to FIG. 4, the above-mentioned second layer of photovoltaic assemblies 12 includes a first row of photovoltaic assembly 121 and a second row of photovoltaic assembly 122 in the horizontal direction. The first row of photovoltaic assembly 121 and the second row of photovoltaic assembly 122 can be relatively close to each other, to make the second layer of photovoltaic assemblies located at the above-mentioned first relative position (as shown in FIG. 2) with respect to the first layer of photovoltaic assemblies; and the first row of photovoltaic assembly 121 and the second row of photovoltaic assembly 122 can be relatively far away from each other, to make the second layer of photovoltaic assemblies 12 located at the above-mentioned second relative position (as shown in FIG. 3 and FIG. 4) with respect to the first layer of photovoltaic assemblies 11. In this example, by disposing two rows of photovoltaic assemblies in the second layer, the number of photovoltaic assembly 1 can be further increased, thereby improving the photovoltaic capacity of the photovoltaic container 100 of the present disclosure.

It should be noted that, as shown in FIG. 4, when the second layer of photovoltaic assemblies 12 is located at the second relative position with respect to the first layer of photovoltaic assemblies 11, the projection of the above-mentioned first row of photovoltaic assembly 121 on the plane of the first layer of photovoltaic assemblies 11 is located at a first side of the first layer of photovoltaic assemblies 11, while the projection of the second row of photovoltaic assembly 122 on the plane of the first layer of photovoltaic assemblies 11 is located at a second side of the first layer of photovoltaic assemblies 11, wherein, the first side is opposite to the second side. By the settings in this example, the arrangement of each photovoltaic assembly 1 becomes more reasonable, each photovoltaic assembly 1 may not be interfered or shaded by one another, thus each photovoltaic assembly 1 can be fully exposed to the sunlight and the working efficiency of each photovoltaic assembly 1 can be maximized.

Furthermore, as shown in FIG. 2 to FIG. 4, a guide structure, disposed on the above-mentioned support frame 2, is configured to guide each row of photovoltaic assembly 1 in the second layer of photovoltaic assemblies 12. Wherein, each row of photovoltaic assembly in the second layer of photovoltaic assemblies 12 is connected to the support frame 2 through a lead screw nut structure 5, and is driven by the lead screw nut structure 5 such that the second layer of photovoltaic assemblies 12 is located at the above-mentioned first relative position and second relative position with respect to the first layer of photovoltaic assemblies 11. In this example, the cooperation of the guide structure and the lead screw nut structure can effectively ensure the motion stability of each row of photovoltaic assembly in the second layer of photovoltaic assemblies 12, thereby realizing the smooth stretching and contracting movements of each row of photovoltaic assembly in the second layer of photovoltaic assemblies 12.

It should be noted that, the lead screw of the above-mentioned lead screw nut structure 5 may be a ball screw so as to reduce the motion resistance.

The above-mentioned guide structure may include a linear slide rail 6. The support frame 2 is connected to each row of photovoltaic assembly in the second layer of photovoltaic assemblies 12 through the liner slide rail 6, to guide each row of photovoltaic assembly in the second layer of photovoltaic assemblies 12.

It should be noted that, there may be a plurality of the above-mentioned lead screw nut structures 5 and the linear slide rails 6, so as to further guide and drive each row of photovoltaic assembly in the second layer of photovoltaic assemblies 12, thereby realizing the smooth stretching and contracting movements of each row of photovoltaic assembly in the second layer of photovoltaic assemblies 12.

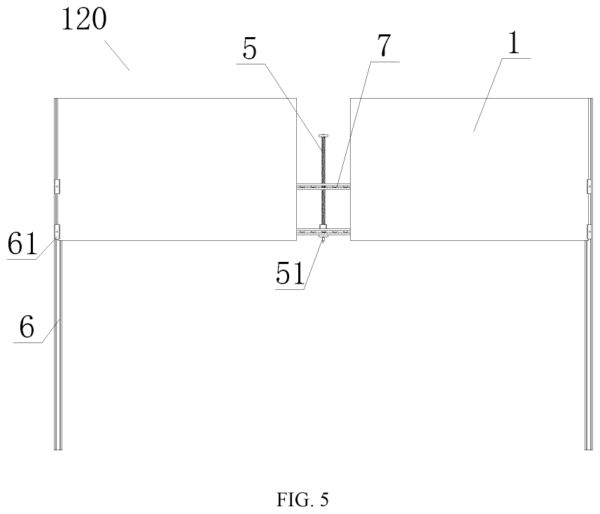

According to a specific embodiment of the present invention, as shown in FIG. 5, each row of photovoltaic assembly in the above mentioned second layer of photovoltaic assemblies 12 can include at least one photovoltaic assembly unit 120, and the assembly unit 120 includes a keel 7 and the photovoltaic assembly 1 mounted on the keel 7. The keel 7 is connected to a screw nut platform 51 of the lead screw nut structure 5 and a slide block 61 of the linear slide rail 6 respectively.

Furthermore, there may be two photovoltaic assemblies 1 in each of the above-mentioned photovoltaic assembly unit 120. Each photovoltaic assembly unit 120 is guided by two linear slide rails 6, and is connected to the support frame 2 by one lead screw nut structure 5.

Furthermore, there are at least two layers of the above-mentioned support frames 2 in the vertical direction, and the two adjacent layers of the support frames 2 are spaced in the vertical direction. Each layer of the above-mentioned photovoltaic assemblies is laid on a different layer of the support frame 2 from one another in one-to-one correspondence. Because the two adjacent layers of the support frames 2 are spaced in the vertical direction, the arrangement facilitates the installation of the above-mentioned each layer of photovoltaic assemblies 1 and prevents interference between the two adjacent layers of photovoltaic assemblies 1.

Each layer of the above-mentioned support frame 2 may include a frame structure constructed by connecting a plurality of connecting rods on the same plane. Wherein, the two adjacent layers of frame structures are fixedly connected. In this example, the frame structure constructed by connecting a plurality of connecting rods on the same plane may facilitate the installation of the photovoltaic assembly 1 and effectively ensure the horizontality of the mounted photovoltaic assembly 1, so as to make the photovoltaic assembly 1 capable of receiving solar energy with the maximum efficiency.

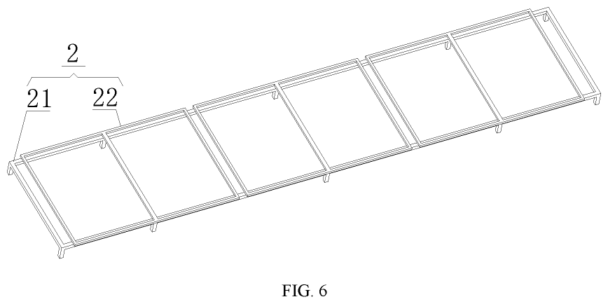

According to a specific embodiment of the present invention, as shown in FIG. 6, there are two layers of the support frames 2 in the vertical direction, the first layer 21 and the second layer 22 respectively. Wherein, each of the first layer 21 and the second layer 22 may include a frame structure constructed by connecting a plurality of connecting rods on the same plane. The frame structure of the first layer 21 and the frame structure of the second layer 22 are fixedly connected.

The operating principle of the present disclosure and preferred embodiments of the present invention are described below.

The technical solution provided by the present disclosure solves the following technical problems: (1) since the existing photovoltaic assembly is directly laid on the top surface of the container, the pressure of the weight of the photovoltaic assembly may easily cause depression and deformation of the iron sheet in the top layer of the container, which reduces the service life of the container; (2) as the existing container has an uneven top surface, it is difficult to satisfy the technical requirements of laying the photovoltaic assembly; (3) since the area of the top surface of the existing container is very limited, the photovoltaic capacity is insufficient when directly laying the photovoltaic assembly on the top surface of the container.

According to the technical solution provided by the present disclosure, as the photovoltaic assembly 1 is mounted on the container body frameworks on four sides of the container via the support frame 2, the container body housing such as iron sheet at the container top is prevented from depressing and deforming due to overloading, thereby prolonging the service life of the container. The photovoltaic assembly 1 is mounted on the support frame 2, and the support frame 2 is mounted on the container body framework on the top of the container through the horizontal adjustment footstands 4. Wherein, the horizontal adjustment footstand 4 can adjust the horizontality of the photovoltaic assembly 1 on the support frame 2 so as to satisfy the technical requirements of laying the photovoltaic assembly 1.

Specifically, when mounting the photovoltaic assembly 1, the photovoltaic assembly 1 can be first mounted on the support frame 2 on the ground, and then the support frame 2 mounted with the photovoltaic assembly 1 is hoisted and mounted onto the top of the container. Such an operation is very easy and has a high safety.

Wherein, a double-laying manner can be adopted in mounting the photovoltaic assembly 1 on the support frame 2, so as to increase the number of laid photovoltaic assembly 1 and improve the photovoltaic capacity of the container. Wherein, the lower layer of photovoltaic assemblies, i.e., the above-mentioned first layer of photovoltaic assemblies 11, is directly fixed on the support frame 2; and the upper layer of photovoltaic assemblies, i.e., the above-mentioned second layer of photovoltaic assemblies 12, is mounted on the support frame 2 through the ball screw nut structure 5, to realize the stretching and contracting movements on the support frame 2 through the ball screw nut structure 5.

Wherein, the above-mentioned lower layer of photovoltaic assemblies is directly fixed on the support frame 2 by means of pressing block connection. The upper layer of photovoltaic assemblies is divided into six separate units, and the photovoltaic assembly 1 of each unit is fixedly mounted on the keel 7 through the pressing block connection. The keel 7 is connected to the above-mentioned screw nut platform 51 of the lead screw nut structure 5, and the lead screw of the lead screw nut structure 5 is mounted on the support frame 2. Wherein, the ball screw can drive the screw nut platform 51 to move to realize the stretching and contacting movements of the upper layer of photovoltaic assemblies on the support frame 2.

The linear slide rail 6 is further mounted on the support frame 2, and the slide block 61 of the linear slide rail 6 is connected to the keel 7 of the upper layer of photovoltaic assemblies. By moving the slide block 61 on the slide rail, smooth stretching and contacting movements of the upper layer of photovoltaic assemblies on the support frame 2 are realized.

The above-mentioned support frame system of photovoltaic assembly can be divided into two or more parts to assemble, and then to fit with the container. More layers of stretching and contacting device for the photovoltaic assemblies may be designed on the above-mentioned support frame 2.

It should be noted that, those skilled in the art is able to combine the relative technical features in the above various embodiments according to actual condition in case of no conflict, so as to obtain the corresponding technical effect. Each specific combination will not be detailed here.

What described above are only some preferable embodiments of the present invention, but they are not intended to limit the present invention. It should be understood that any simple modifications, equivalent changes and replacements may be made therein without departing from the theory of the present disclosure, which should also be seen in the scope of the technical solutions of the present disclosure.

1. A photovoltaic container, comprising a photovoltaic assembly (1), a support frame (2) and a container body (3); wherein the container body (3) comprises a container body framework;
the photovoltaic assembly (1) is mounted on the container body framework through the support frame (2) and located outside the container body (3), to make the photovoltaic assembly (1) supported by the container body framework.

2. The photovoltaic container of claim 1, wherein,
the photovoltaic assembly (1) is located above a top surface of the container body (3);
the photovoltaic assembly (1) is mounted on the support fame (2), the support fame (2) is mounted on a first part of the container body framework, the first part is located on a top of the container body (3).

3. The photovoltaic container of claim 1, further comprising a horizontal adjustment footstand (4);
wherein the support frame (2) is mounted on the container body framework through the horizontal adjustment footstand (4), to adjust horizontality of the photovoltaic assembly (1) on the support frame (2) by the horizontal adjustment footstand (4).

4. The photovoltaic container of claim 1, wherein,
the photovoltaic container has at least two layers of photovoltaic assemblies in a vertical direction;
wherein, each of layers of photovoltaic assemblies is moveable relative to one another, to move to a first relative position at which the at least two layers of photovoltaic assemblies overlap each other in the vertical direction and a second relative position at which the at least two layers of photovoltaic assemblies are spread out relatively.

5. The photovoltaic container of claim 4, wherein,
the layers of photovoltaic assemblies have a first layer of photovoltaic assemblies (11) and a second layer of photovoltaic assemblies (12) which are adjacently disposed;
the first layer of photovoltaic assemblies (11) is fixed on the support frame (2);
the second layer of photovoltaic assemblies (12) is movably disposed on the support frame (2), to move to the first relative position and the second relative position with respect to the first layer of photovoltaic assemblies (11).

6. The photovoltaic container of claim 5, wherein,
the second layer of photovoltaic assemblies (12) has a first row of photovoltaic assembly (121) and a second row of photovoltaic assembly (122) in a horizontal direction;
the first row of photovoltaic assembly (121) and the second row of photovoltaic assembly (122) can be relatively close to each other, to make the second layer of photovoltaic assemblies (12) located at the first relative position with respect to the first layer of photovoltaic assemblies (11); and the first row of photovoltaic assembly (121) and the second row of photovoltaic assembly (122) can be relatively far away from each other, to make the second layer of photovoltaic assemblies (12) located at the second relative position with respect to the first layer of photovoltaic assemblies (11).

7. The photovoltaic container of claim 6, wherein,
a linear slide rail (6) is disposed on the support frame (2), the support frame (2) is connected to each row of photovoltaic assembly in the second layer of photovoltaic assemblies (12) through the linear slide rail (6), to guide the each row of photovoltaic assembly in the second layer of photovoltaic assemblies (12);
wherein, the each row of photovoltaic assembly in the second layer of photovoltaic assemblies (12) is connected to the support frame (2) through a lead screw nut structure (5), to be driven by the lead screw nut structure (5) so as to make the second layer of photovoltaic assemblies (12) located at the first relative position and the second relative position with respect to the first layer of photovoltaic assemblies (11).

8. The photovoltaic container of claim 7, wherein,
the each row of photovoltaic assembly in the second layer of photovoltaic assemblies (12) comprises at least one photovoltaic assembly unit (120);
the photovoltaic assembly unit (120) comprises a keel (7) and the photovoltaic assembly (1) mounted on the keel (7);
the keel (7) is connected to a screw nut platform (51) of the lead screw nut structure (5) and a slide block (61) of the linear slide rail (6) respectively.

9. The photovoltaic container of claim 4 wherein,
there are at least two layers of support frames (2) in the vertical direction;
two adjacent layers of the support frames (2) are spaced in the vertical direction, and each layer of photovoltaic assemblies is disposed on a different layer of the support frame (2) from one another in one-to-one correspondence.

10. The photovoltaic container of claim 9, wherein,
each layer of the support frame (2) comprises a frame structure constructed by connecting a plurality of connecting rods on the same plane;
wherein, two adjacent layers of frame structures are fixedly connected.

11. The photovoltaic container of claim 2, further comprising a horizontal adjustment footstand (4);
wherein the support frame (2) is mounted on the container body framework through the horizontal adjustment footstand (4), to adjust horizontality of the photovoltaic assembly (1) on the support frame (2) by the horizontal adjustment footstand (4).

12. The photovoltaic container of claim 2, wherein,
the photovoltaic container has at least two layers of photovoltaic assemblies in a vertical direction;
wherein, each of layers of photovoltaic assemblies is moveable relative to one another, to move to a first relative position at which the at least two layers of photovoltaic assemblies overlap each other in the vertical direction and a second relative position at which the at least two layers of photovoltaic assemblies are spread out relatively.

13. The photovoltaic container of claim 3, wherein,
the photovoltaic container has at least two layers of photovoltaic assemblies in a vertical direction;
wherein, each of layers of photovoltaic assemblies is moveable relative to one another, to move to a first relative position at which the at least two layers of photovoltaic assemblies overlap each other in the vertical direction and a second relative position at which the at least two layers of photovoltaic assemblies are spread out relatively.

14. The photovoltaic container of claim 5, wherein,
there are at least two layers of support frames (2) in the vertical direction;
two adjacent layers of the support frames (2) are spaced in the vertical direction, and each layer of photovoltaic assemblies is disposed on a different layer of the support frame (2) from one another in one-to-one correspondence.

15. The photovoltaic container of claim 6, wherein,
there are at least two layers of support frames (2) in the vertical direction;
two adjacent layers of the support frames (2) are spaced in the vertical direction, and each layer of photovoltaic assemblies is disposed on a different layer of the support frame (2) from one another in one-to-one correspondence.

16. The photovoltaic container of claim 7, wherein,
there are at least two layers of support frames (2) in the vertical direction;
two adjacent layers of the support frames (2) are spaced in the vertical direction, and each layer of photovoltaic assemblies is disposed on a different layer of the support frame (2) from one another in one-to-one correspondence.

17. The photovoltaic container of claim 8, wherein,
there are at least two layers of support frames (2) in the vertical direction;
two adjacent layers of the support frames (2) are spaced in the vertical direction, and each layer of photovoltaic assemblies is disposed on a different layer of the support frame (2) from one another in one-to-one correspondence.
